(19) United States
(12) Patent Application Publication
(10) Pub. No.: US 2016/0093676 A1
(43) Pub. Date: Mar. 31, 2016

(54) DISPLAY PANEL AND METHOD FOR MANUFACTURING THE SAME

(71) Applicant: Ye Xin Technology Consulting Co., Ltd., Hsinchu (TW)

(72) Inventors: I-WEI WU, Hsinchu (TW); JUNG-AN CHENG, Hsinchu (TW)

(21) Appl. No.: 14/569,084

(22) Filed: Dec. 12, 2014

(30) Foreign Application Priority Data
Sep. 30, 2014 (TW) 103134106

(51) Int. Cl. H01L 27/32; H01L 51/52; H01L 51/56

(52) U.S. Cl. CPC H01L 27/322; H01L 27/3211; H01L 27/3244; H01L 51/56; H01L 51/5284; H01L 51/5237; H01L 2251/5369; H01L 2227/323

(57) ABSTRACT

A display panel includes an array substrate including a thin film transisitors array, a lighting device formed on a surface of the array substrate where the thin film transistors array is formed to emit a backlight, and a color conversion layer formed on a side of the array substrate opposite to the lighting device. The display panel defines a number of pixel areas, each of the pixel areas includes at least three sub-pixels to correspondingly emit lights with three-primary colors. The color conversion layer includes a number of quantum dot blocks corresponding to the sub-pixels to convert the backlight to the lights with three-primary colors.

### FIELD

The disclosure generally relates to display technologies, and particularly to a display panel and a method for manufacturing the same.

### BACKGROUND

An organic light emitting diode (OLED) display panel usually employs different OLED materials to emit light of three-primary colors. However, luminance of three-primary colors light emitted by the OLED materials are different. Luminance decay of each OLED material is also different. Thus, color gamut of the OLED display panel is compromised. In order to improve the color gamut of the OLED display panel, a number of circuits need to be set on the OLED display panel to compensate for the differences of luminance of three-primary colors light and luminance decay of different OLED material, which increases complexity of the circuits and cost of the OLED display panel.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the views.

FIG. 1 is an isometric view of a first embodiment of a display panel.

FIG. 2 is a cross-sectional view of the display panel of FIG. 1, taken along line II-II.

FIG. 3 is a cross-sectional view of a second embodiment of a display panel.

FIG. 4 is a flowchart of an exemplary embodiment of a method to manufacture the display panel of FIG. 1.

FIG. 5 is a cross-sectional views corresponding to block 401 of FIG. 4.

FIG. 6 is a cross-sectional views corresponding to block 402 of FIG. 4.

FIG. 7 is a cross-sectional views corresponding to block 403 of FIG. 4.

FIG. 8 is a cross-sectional views corresponding to block 404 of FIG. 4.

FIG. 9 is a cross-sectional views corresponding to block 405 of FIG. 4.

FIG. 10 is a flowchart of an exemplary embodiment of a method to manufacture the display panel of FIG. 3.

FIG. 11 is a cross-sectional views corresponding to block 801 of FIG. 10.

FIG. 12 is a cross-sectional views corresponding to block 802 of FIG. 10.

FIG. 13 is a cross-sectional views corresponding to block 803 of FIG. 10.

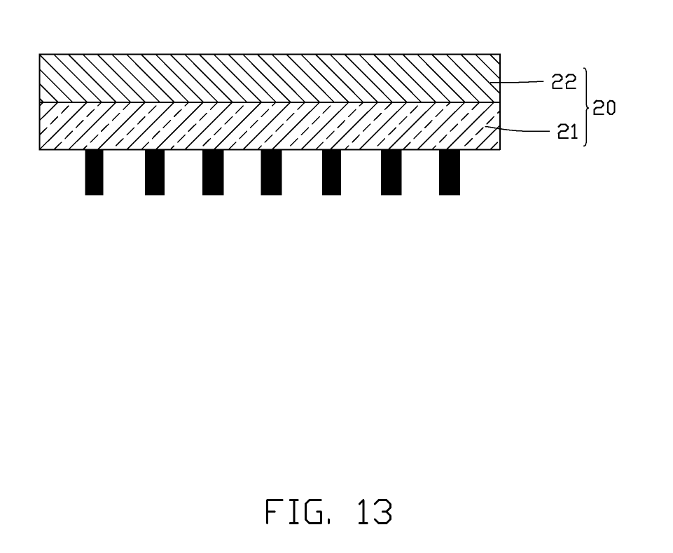

FIG. 14 is a cross-sectional views corresponding to block 804 of FIG. 10.

FIG. 15 is a cross-sectional views corresponding to block 805 of FIG. 10.

FIG. 16 is a cross-sectional views corresponding to block 806 of FIG. 10.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series and the like.

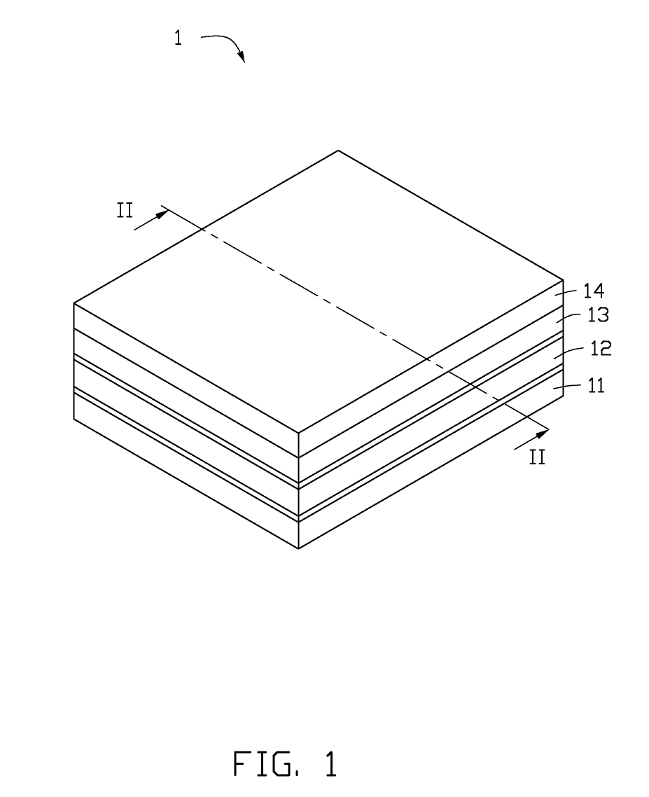

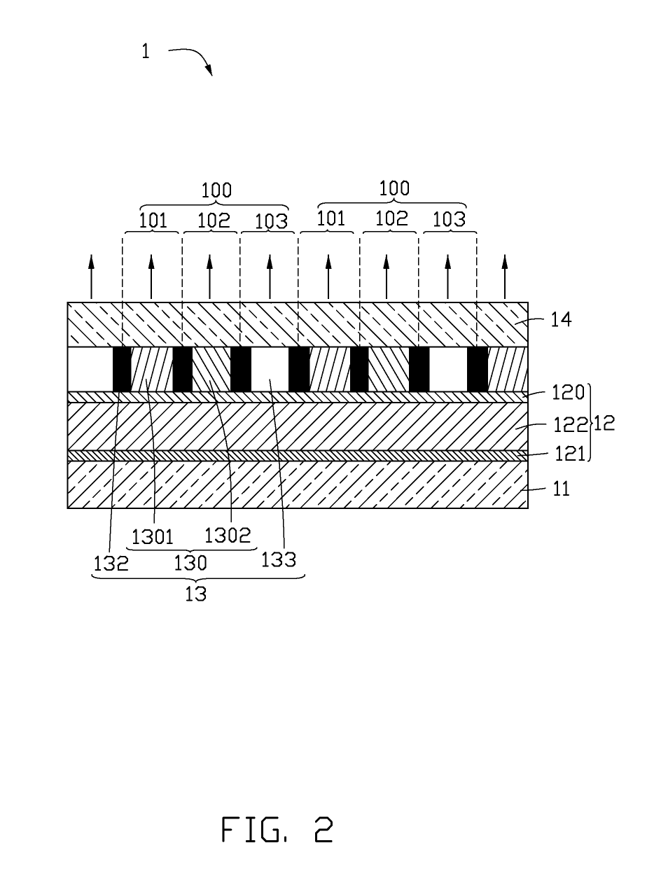

FIG. 1 illustrates an isometric view of a first embodiment of a display panel 1. FIG. 2 illustrates a cross-sectional view of the display panel 1 of FIG. 1, taken along line II-II. The display panel 1 defines a number of pixel areas 100. FIG. 2 illustrates two pixel areas 100 for example. In this embodiment, the display panel 1 is an organic light emitting diode (OLED) display panel.

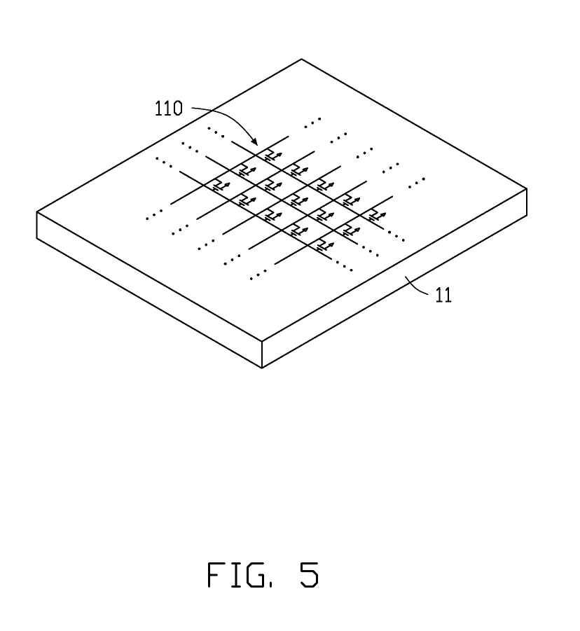

The display panel 1 includes an array substrate 11 which includes a thin film transistors (TFTS) array 110 (see FIG. 5), a lighting device 12 formed on the array substrate 11, a color conversion layer 13 formed on a light output side of the lighting device 12, and a passivation layer 14 covering the color conversion layer 13 at a side of the color conversion layer 13 opposite to the lighting device 12.

Each of the pixel areas 100 includes at least a first sub-pixel 101, a second sub-pixel 102, and a third sub-pixel 103 for respectively emitting lights with different colors. The lighting device 12 emits a backlight. The TFTS array 110 (see FIG. 5) controls a luminance of the lighting device 12 corresponding to the first sub-pixel 101, the second sub-pixel 102, and the third sub-pixel 103. In this embodiment, the lighting device 12 is an OLEDS array emitting a blue backlight.

In this embodiment, the display panel 1 employs three-primary color lights to display the full color image. The first sub-pixel 101 emits a red light. The second sub-pixel 102 emits a green light. The third sub-pixel 103 emits a blue light.

The color conversion layer 13 includes a number of quantum dot blocks 130 and a black matrix 132. The black matrix 132 defines the first sub-pixel 101, the second sub-pixel 102, and the third sub-pixel 103. The quantum dot blocks 130 are correspondingly formed on the first sub-pixel 101 and the second sub-pixel 102. The quantum dot blocks 130 in the first sub-pixel 101 and the second sub-pixel 102 respectively convert the backlight from the lighting device 12 to lights with different colors. The black matrix 132 is formed on a top of the lighting device 12. The quantum dot blocks 130 are formed in the first sub-pixel 101 and the second sub-pixel 102 by an ink jet printing process or a micro-contact printing process.

The quantum dot blocks 130 are made of an inorganic nano-material which can convert the backlight having a wavelength less than a wavelength of light with a specific color to light with the specific color. In this embodiment, the color conversion layer 13 includes a number of red quantum dot blocks 1301 formed in the first sub-pixels 101, a number of green quantum dot blocks 1302 formed in the second sub-pixels 102, and a number of transparent blocks 133 corresponding to the third sub-pixel 103. Because the lighting device 12 emits the blue backlight. The blue backlight passing through the first sub-pixels 101 is converted to the red light by the red quantum dot blocks 1301. The blue backlight passing through the second sub-pixels 102 is converted to the green light by the green quantum dot blocks 1302. The blue backlight passes through the transparent blocks 133 and then comes out from the third sub-pixels 103. Thus, most of the blue backlight can pass through the color conversion layer 13 and be used to display an image. A backlight availability of the display panel 1 is improved.

The passivation layer 14 is made of a transparent material. The passivation layer 14 covers a side of the color conversion layer 13 opposite to the lighting device 12 to protect the quantum dot blocks 130 from external pollution.

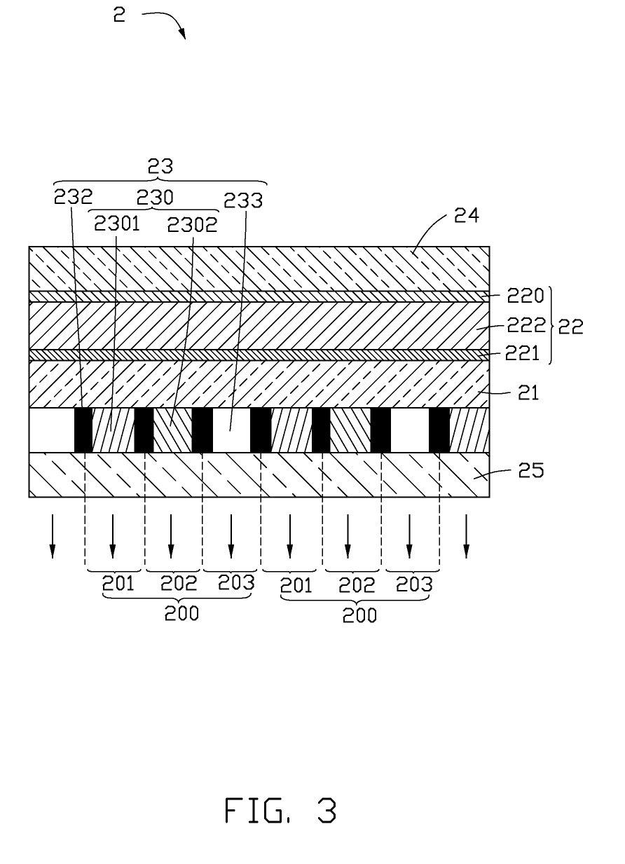

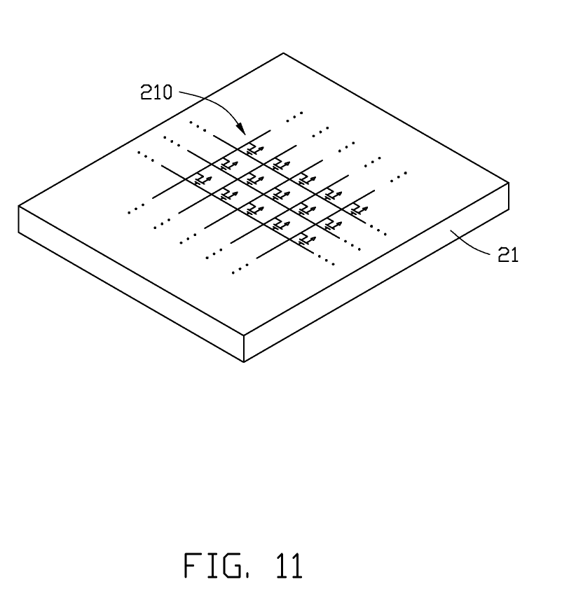

FIG. 3 illustrates a cross-sectional view of a second embodiment of a display panel 2. The display panel 2 defines a number of pixel areas 200. FIG. 2 illustrates two pixel areas 200 for example. In this embodiment, the display panel 2 includes an array substrate 21 having a TFTS array 210 (see FIG. 11), a lighting device 22 formed on the array substrate 21, a color conversion layer 23 formed on a side of the array substrate 21 opposite to the lighting device 22, a first passivation layer formed on a side of the lighting device 22 opposite to the array substrate 21, and a second passivation layer 25 formed on the color conversion layer 23 opposite to the array substrate 21.

Each of the pixel areas 200 includes at least a first sub-pixel 201, a second sub-pixel 202, and a third sub-pixel 203 for respectively emitting lights with different colors. The lighting device 23 emits a backlight. The array substrates 21 are made of a transparent material. The TFTS array 210 (see FIG. 11) control a luminance of the light device 23 corresponding to the first sub-pixel 101, the second sub-pixel 102, and the third sub-pixel 103. In this embodiment, the lighting device 12 is an OLEDS array emitting a blue backlight.

In this embodiment, the display panel 2 employs three-primary color lights to display the full color image. The first sub-pixel 201 emits a red light. The second sub-pixel 202 emits a green light. The third sub-pixel 203 emits a blue light.

The color conversion layer 23 includes a number of quantum dot blocks 230 and a black matrix 232. The black matrix 232 defines the first sub-pixel 201, the second sub-pixel 202, and the third sub-pixel 203. The quantum dot blocks 230 are correspondingly formed in the first sub-pixel 201 and the second sub-pixel 202 defined by the black matrix 232. The quantum dot blocks 230 in the first sub-pixel 201 and the second sub-pixel 202 respectively convert the backlight from the lighting device 22 to light with different colors. The black matrix 232 is formed on a side of the array substrate 21 opposite to the lighting device 22. The quantum dot blocks 130 are formed in the first sub-pixel 101 and the second sub-pixel 102 by an ink jet printing process or a micro-contact printing process.

The quantum dot blocks 230 are made of an inorganic nano-material which can convert the backlight having a wavelength less than a wavelength of light with a specific color to light with the specific color. In this embodiment, the color conversion layer 23 includes a number of red quantum dot block 2301 formed in the first sub-pixel 201, a number of green quantum dot blocks 2302 formed in the second sub-pixel 202, and a transparent block 233 formed in the third sub-pixel 203. Because the lighting device 22 emits the blue backlight. The blue backlight passing through the first sub-pixel 201 is converted to the red light by the red quantum dot blocks 2301. The blue backlight passing through the second sub-pixel 202 is converted to the green light by the green quantum dot blocks 2302. The blue backlight passing through the transparent block 233 comes out from the third sub-pixel 203. Thus, most of the blue backlight can pass through the color conversion layer 13 and be used to display an image. A backlight availability of the display panel 2 is improved.

The first passivation layer 24 is formed on a side of the lighting device 22 opposite to the array substrate 21. The second passivation layer 25 covers on a side of the color conversion layer 23 opposite to the lighting device 12 to protect the quantum dot blocks 230 from external pollution. The second passivation layer 25 is made of a transparent material.

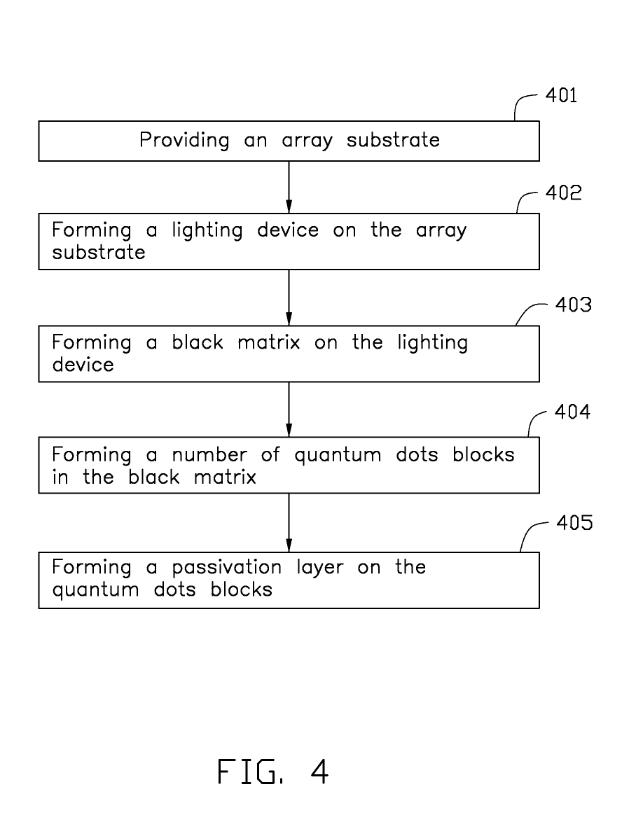

Referring to FIG. 4, a flowchart is presented in accordance with an exemplary embodiment of a method to manufacture the first embodiment of the display panel 1 is being thus illustrated. The example method is provided by way of example, as there are a variety of ways to carry out the method. The method described below can be carried out using the configurations illustrated in FIGS. 1 and 2, for example, and various elements of these figures are referenced in explaining example method. Each blocks shown in FIG. 4 represents one or more processes, methods or blocks is by example only and order of the blocks can change according to the present disclosure. The exemplary method can begin at block 401.

At block 401, also referring to FIG. 5, an array substrate 11 is provided. The array substrate 11 includes a TFTS array 110.

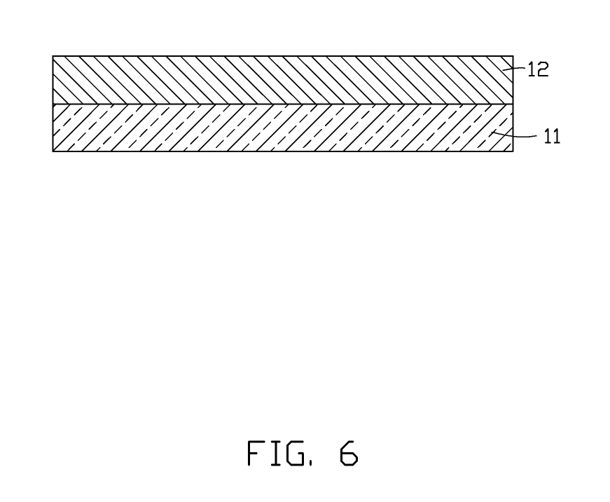

At block 402, also referring to FIG. 6, a lighting device 12 is formed on a surface of the array substrate 11 where the TFTS array 110 is formed. The lighting device 12 and the array substrate 11 are combined as a lighting array substrate 10. The TFTS array 110 is connected to the lighting device 12 to control luminance of the lighting device 12. In this embodiment, the lighting device 12 is an OLEDS array emitting a blue backlight.

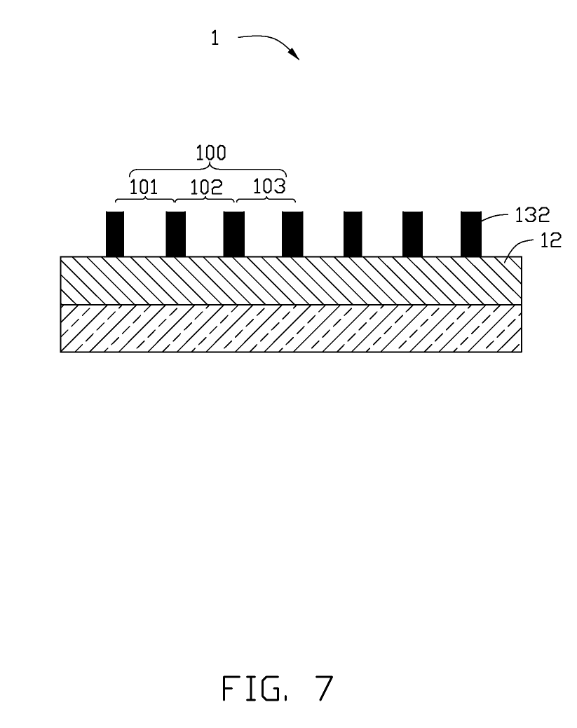

At block 403, also referring to FIG. 7, a black matrix 132 is formed on a side of the lighting device opposite to the array substrate 11 to define a number of sub-pixel 101, 102, and 103. In this embodiment, the display panel 1 defines a number of pixel areas 100. Each of the pixel areas 100 includes at least a first sub-pixel 101, a second sub-pixel 102, and a third sub-pixel 103 for respectively emitting lights with different colors. The display panel 1 employs three-primary color lights to display the full color image. The first sub-pixel 101 emits a red light. The second sub-pixel 102 emits a green light. The third sub-pixel 103 emits a blue light. The black matrix 132 is made of an opaque material to reduce a light interference between two adjacent sub-pixels 101, 102, or 103.

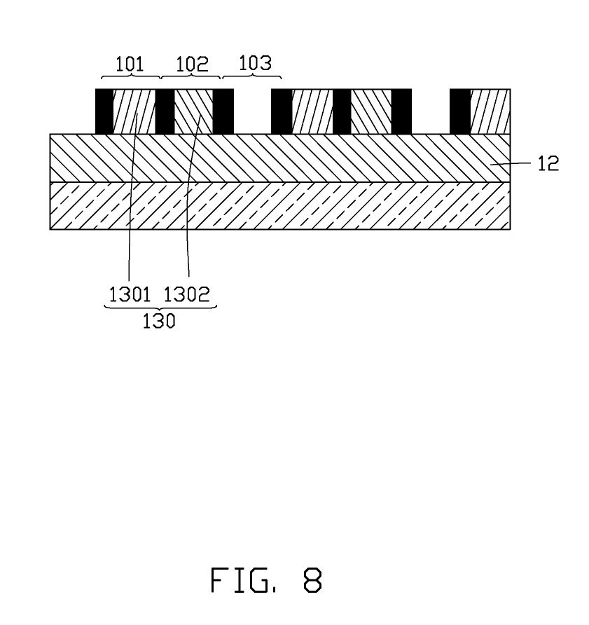

At block 404, also referring to FIG. 8, a number of quantum dot blocks 130 are correspondingly formed in the first sub-pixel 101 and the second sub-pixel 102. The quantum dot blocks 130 convert the backlight from the lighting device 12 to a light with one of three-primary colors. The quantum dot blocks 130 can be a number of red quantum dot blocks 1301 formed in the first sub-pixel 101 and a number of green quantum dot blocks 1302 formed in the second sub-pixel 102. The red quantum dot blocks 1301 convert the light having a wavelength less than a wavelength of red light to red light. The green quantum dot blocks 1302 convert the light having a wavelength less than a wavelength of green light to green light. The quantum dot blocks 130 are formed in the first sub-pixel 101 and the second sub-pixel 102 by an inkjet printing process or a micro-contact printing process.

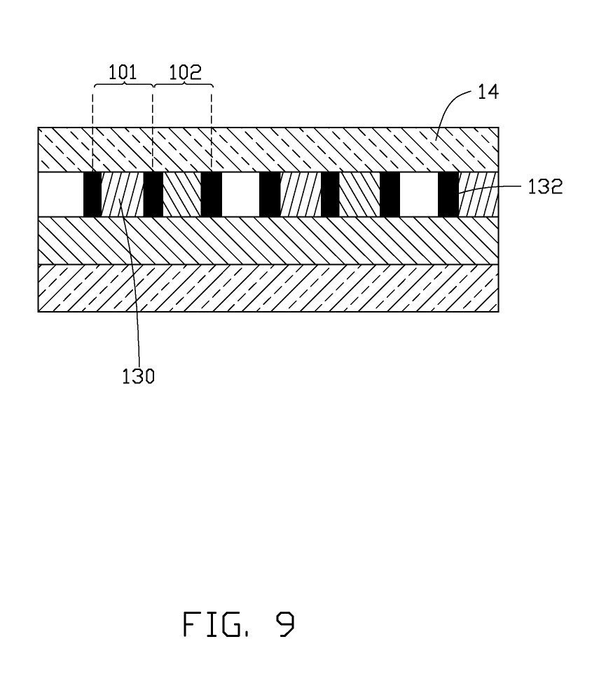

At block 405, also referring to FIG. 9, a passivation layer 14 is formed on a side of the black matrix 132 opposite to the lighting device 12 to seal the quantum dot blocks 130 in the first sub-pixel 101 and the second sub-pixel 102. The passivation layer 14 is made of a transparent material.

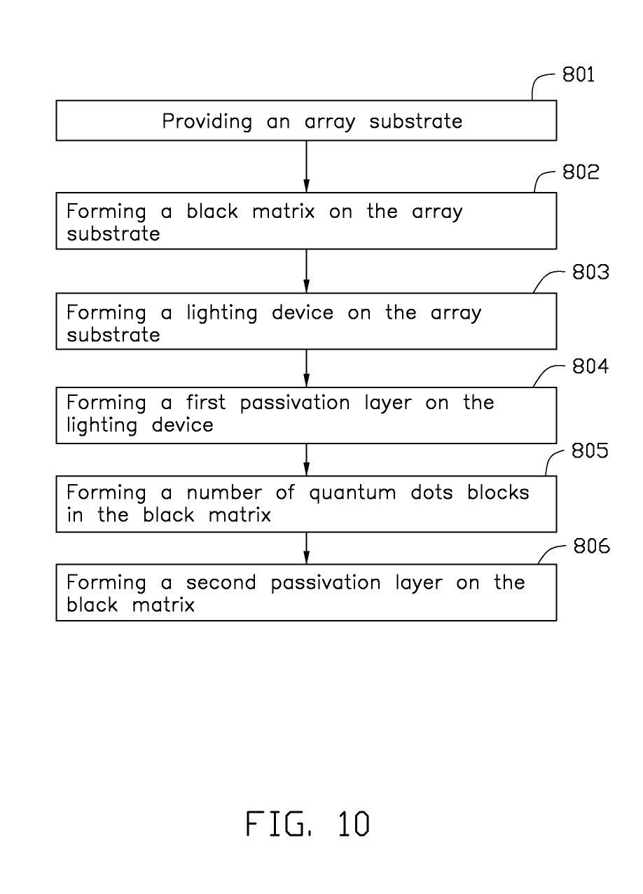

Referring to FIG. 10, a flowchart is presented in accordance with an exemplary embodiment of a method to manufacture the second embodiment of the display panel 2 is being thus illustrated. The example method is provided by way of example, as there are a variety of ways to carry out the method. The method described below can be carried out using the configurations illustrated in FIGS. 1 and 3, for example, and various elements of these figures are referenced in explaining example method. Each blocks shown in FIG. 3 represents one or more processes, methods or blocks is by example only and order of the blocks can change according to the present disclosure. The exemplary method can begin at block 401.

At block 801, also referring to FIG. 11, an array substrate 21 is provided. The array substrate 21 includes a TFTS array 210. The array substrate 21 is made of a transparent material.

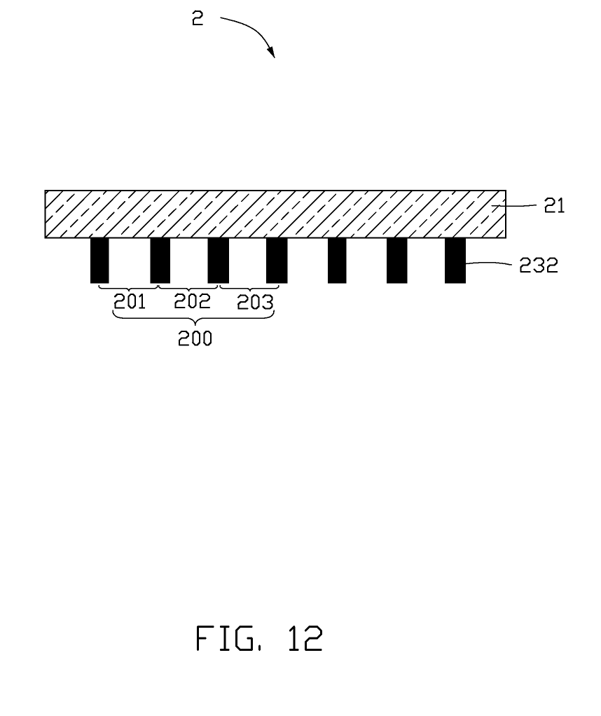

At block 802, also referring to FIG. 12, a black matrix 232 is formed on a side of the array substrate 21 opposite to the TFTS array 210 defining a number of sub-pixels 201, 202, and 203. In this embodiment, the display panel 2 defines a number of pixel areas 200. Each of the pixel areas 200 includes at least a first sub-pixel 201, a second sub-pixel 202, and a third sub-pixel 203 for respectively emitting light with different colors. The display panel 2 employs three-primary color lights to display the full color image. The first sub-pixel 201 emits a red light. The second sub-pixel 202 emits a green light. The third sub-pixel 203 emits a blue light. The black matrix 232 is made of an opaque material to reduce light interference between two adjacent sub-pixels 201, 202, or 203.

At block 803, a lighting device 22 is formed on a surface of the array substrate 21 where the TFTS array 210 is formed. The lighting device 22 and the array substrate 21 are combined as a lighting array substrate 20. The TFTS array 210 is connected to the lighting device 22 to control luminance of the lighting device 22. In this embodiment, the lighting device 22 is an OLEDS array emitting a blue backlight.

In other embodiments, the lighting device 33 can be formed on the array substrate 21 at first, and then the black matrix 232 is formed on a side of the array substrate 21 opposite to the lighting device 33.

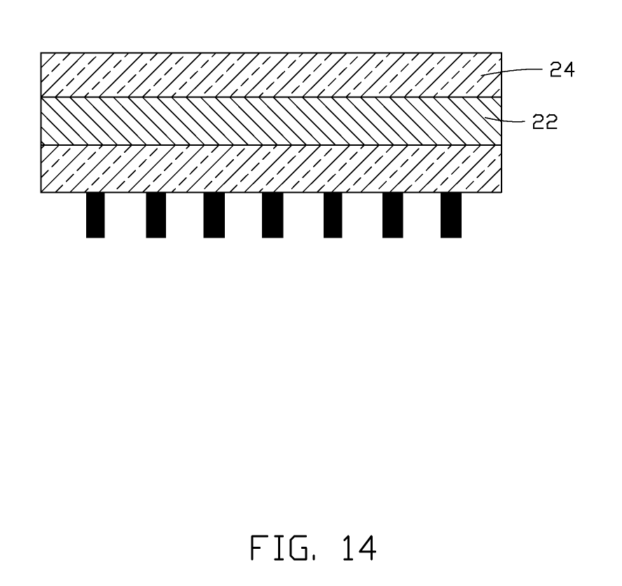

At block 804, also referring to FIG. 14, a first passivation layer 24 is formed on a side of the lighting device 33 opposite to the array substrate 21.

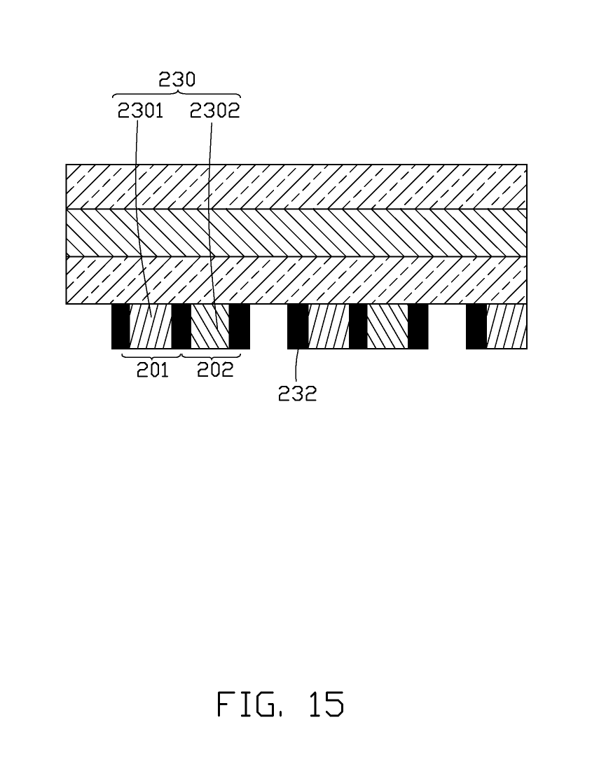

At block 805, also referring to FIG. 15, a number of quantum dot blocks 230 are correspondingly formed in the first sub-pixel 201 and the second sub-pixel 202. The quantum dot blocks 230 convert the backlight from the lighting device 22 to a light with one of three-primary colors. The quantum dot blocks 230 can be a number of red quantum dot blocks 2301 formed in the first sub-pixel 201 and a number of green quantum dot blocks 2302 formed in the second sub-pixel 202. The red quantum dot blocks 2301 convert the light having a wavelength less than a wavelength of red light to red light. The green quantum dot blocks 2302 convert the light having a wavelength less than a wavelength of green light to green light. The quantum dot blocks 230 are formed in the first sub-pixel 201 and the second sub-pixel 202 by an inkjet printing process or a micro-contact printing process.

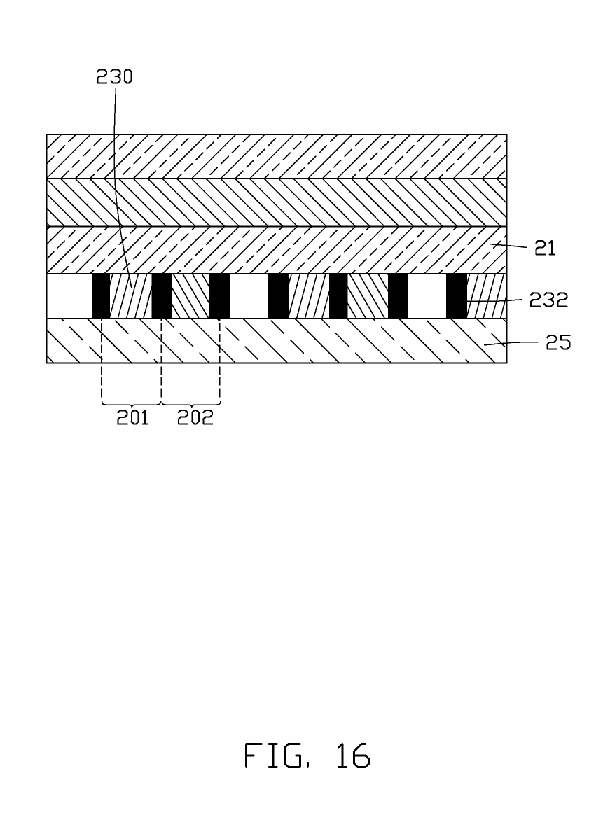

At block 806, also referring to FIG. 16, a second passivation layer 25 is formed on a side of the black matrix 232 opposite to the lighting device 22 sealing the quantum dot blocks 230 in the first sub-pixel 201 and the second sub-pixel 202. The second passivation layer 25 is made of a transparent material.

It is believed that the present embodiments and their advantages will be understood from the foregoing description, and it will be apparent that various changes may be made thereto without departing from the scope of the disclosure or sacrificing all of its material advantages.

What is claimed is:

1. A display panel comprising:
an array substrate;
a lighting device formed at a side of the array substrate to emit a backlight; and
a color conversion layer in an optical transmission path of the backlight, the color conversion layer is capable of receiving the backlight, converting wavelengths of the backlight to predetermined wavelengths, and outputting the backlight with the predetermined wavelengths;
wherein the display panel defines a plurality of pixel areas, each of the pixel areas comprises at least three sub-pixels to correspondingly emit lights with three-primary colors, the color conversion layer comprises a plurality of quantum dot blocks corresponding to the sub-pixels to correspondingly convert the wavelengths of the backlight to the predetermined wavelengths of the three-primary colors.

2. The display panel of claim 1, wherein the three sub-pixels of one pixel areas comprises a first sub-pixel to emit a red light, a second sub-pixel to emit a green light, and a third sub-pixel to emit a blue light.

3. The display panel of claim 2, wherein the color conversion layer further comprises a black matrix formed on a side of the array substrate opposite to the lighting device, the black matrix defines the first sub-pixel, the second sub-pixel, and the third sub-pixel, and the quantum dot blocks are correspondingly formed in the first sub-pixel and the second sub-pixel defined by the black matrix.

4. The display panel of claim 2, wherein the lighting device emit a blue backlight.

5. The display panel of claim 4, wherein the quantum dot blocks are a plurality of red quantum dot blocks formed in the first sub-pixels and a plurality of green quantum dot blocks formed in the second sub-pixel, and the color conversion layer further comprises a plurality of transparent blocks corresponding to the third sub-pixels.

6. The display panel of claim 1, wherein the lighting device is an organic light emitting diodes array.

7. The display panel of claim 1, further comprising a first passivation layer formed on a side of the lighting device opposite to the array substrate.

8. The display panel of claim 1, further comprising a second passivation layer formed on a side of the color conversion layer opposite to the array substrate.

9. A method of manufacturing a display panel, the display panel defining a number of pixel areas, each of the pixel areas comprising at least three sub-pixels to correspondingly emit lights with three-primary colors, the method comprising:
providing an array substrate, the array substrate comprising a thin film transistors array formed on a surface of the array substrate;
forming a lighting device on the array substrate to connect with the thin film transistors array for emitting a backlight, wherein the lighting device and the array substrate are combined as a lighting array substrate;
forming a plurality of quantum dot blocks corresponding to the sub-pixels to convert the backlight to the lights with three-primary colors; and
forming a first passivation layer on a side of the quantum dot blocks opposite to the lighting array substrate.

10. The manufacturing method of claim 9, further comprising:
forming a black matrix on the light array substrate to separate the quantum dot blocks and the transparent blocks from each other.

11. The manufacturing method of claim 10, wherein the black matrix, the quantum dot blocks, and the transparent blocks are formed at a side of the lighting device opposite to the array substrate.

12. The manufacturing method of claim 10, wherein the black matrix, the quantum dot blocks, and the transparent blocks are formed at a side of the array substrate opposite to the lighting device.

13. The manufacturing method of claim 12, further comprising:
forming a second passivation layer on a side of the lighting device opposite to the array substrate.

14. A display panel comprising:
a substrate layer having a first surface and a second surface opposite, and substantially parallel, to the first surface;
a light emitting layer formed on the first surface of the substrate; and
a color conversion layer formed on the light emitting layer;
wherein, the light emitted from the light emitting layer is optically transmitted to the color conversion layer and the color conversion layer receives the light emitted by the color conversion layer and converts wavelengths of the emitted light to predetermined wave lengths outputted from the color conversion layer;
wherein, the color conversion layer comprises a plurality of quantum dot blocks to convert the light emitted from the wavelength of the light emitting layer to one of the predetermined three-primary color wavelengths; and
wherein, an area of the color conversion layer outputting one of the three-primary colors forms a sub-pixel and an area with of at least three sub-pixels, having at least one sub-pixel outputting each of the three-primary colors, forms a pixel.

15. The display panel of claim 14, wherein there are a first sub-pixel, a second sub-pixel, and a third sub-pixel are formed, the first sub-pixel emits a red light, the second sub-pixel emits a green light, and the third sub-pixel emits a blue light.

16. The display panel of claim 15, wherein the lighting device emit a blue backlight.

17. The display panel of claim 16, wherein the quantum dot blocks are a plurality of red quantum dot blocks formed in the first sub-pixels and a plurality of green quantum dot blocks formed in the second sub-pixel, and the color conversion layer further comprises a plurality of transparent blocks corresponding to the third sub-pixels.

18. The display panel of claim 14, further comprising a first passivation layer formed on a surface of the lighting device opposite to the substrate layer.
